(19) United States
(12) Patent Application Publication
(10) Pub. No.: US 2026/0280076 A1
(43) Pub. Date: Sep. 17, 2026

(54) WIRING BOARD AND BATTERY DEVICE

(71) Applicant: DENSO CORPORATION, Kariya-city (JP)

(72) Inventors: Kazuo MATSUKAWA, Kariya-city (JP); Masaaki KITAGAWA, Kariya-city (JP)

(73) Assignee: DENSO CORPORATION, Kariya-city (JP)

(21) Appl. No.: 19/673,161

(22) Filed: May 11, 2026

Related U.S. Application Data
(63) Continuation of application No. PCT/JP2024/037360, filed on Oct. 21, 2024.

(30) Foreign Application Priority Data
Nov. 13, 2023 (JP) 2023-193175

(51) Int. Cl. H01M 50/569; G01R 31/389; H01M 50/204; H01M 50/298; H01M 50/519; H05K 1/02

(52) U.S. Cl. CPC H01M 50/569; G01R 31/389; H01M 50/204; H01M 50/298; H01M 50/519; H05K 1/0296; H05K 2201/09227; H05K 2201/09236; H05K 2201/09245

(57) ABSTRACT

A wiring board for connecting positive and negative electrode terminals of multiple battery cells includes an electrically insulating base material and laminated conductive patterns arranged in different layers, which are electrically connected by an interlayer connection member. The wiring includes multiple pair wiring portions, each having a positive electrode wiring section connected to the positive electrode terminal of a respective battery cell and a negative electrode wiring section connected to the negative electrode terminal of that battery cell. In each pair wiring portion, the positive and negative electrode wiring sections extend in parallel.

### CROSS REFERENCE TO RELATED APPLICATIONS

The present application is a continuation application of International Patent Application No. PCT/JP2024/037360 filed on Oct. 21, 2024, which designated the U.S. and claims the benefit of priority from Japanese Patent Application No. 2023-193175 filed on Nov. 13, 2023. The entire disclosures of all of the above applications are incorporated herein by reference.

### TECHNICAL FIELD

The present disclosure relates to a wiring board and a battery device.

### BACKGROUND

A battery monitoring device may monitor a battery including battery cells.

### SUMMARY

According to an aspect of the present disclosure, a wiring board is connected to a positive electrode terminal and a negative electrode terminal of each of battery cells. the wiring board includes a base material and a wiring. The base material is electrically insulated. The wiring includes conductive patterns and an interlayer connection member. The conductive patterns are layered with the base material interposed between the conductive patterns. The interlayer connection member electrically connects the conductive patterns in different layers. The wiring may include pair wiring portions, each of which has a positive wiring section and a negative electrode wiring section. The positive electrode wiring section is connected to the positive electrode terminal of a respective one of the battery cells, and the negative electrode wiring section connected to the negative electrode terminal of the respective one of the battery cells. The positive electrode wiring section and the negative electrode wiring section may extend in parallel.

### BRIEF DESCRIPTION OF DRAWINGS

FIG. 1 is a diagram showing a schematic configuration of a battery device.

FIG. 2 is a cross-sectional view taken along line II-II in FIG. 1.

FIG. 3 is a cross-sectional view taken along line III-III in FIG. 1.

FIG. 4 is a cross-sectional view taken along line IV-IV in FIG. 1.

FIG. 5 is a cross-sectional view taken along line V-V in FIG. 1.

FIG. 6 is a diagram showing the schematic configuration of a battery monitoring device and a flexible wiring board according to a first embodiment.

FIG. 7 is a diagram showing the schematic configuration of a battery device according to a second embodiment.

FIG. 8 is a cross-sectional view taken along line VIII-VIII in FIG. 7.

FIG. 9 is a cross-sectional view taken along line IX-IX in FIG. 7.

FIG. 10 is a cross-sectional view taken along line X-X in FIG. 7.

FIG. 11 is a diagram showing a schematic configuration of a battery device according to a third embodiment.

FIG. 12 is a cross-sectional view taken along line XII-XII in FIG. 11.

FIG. 13 is a cross-sectional view taken along line XIII-XIII in FIG. 11.

FIG. 14 is a cross-sectional view taken along line XIV-XIV in FIG. 11.

FIG. 15 is a diagram showing a schematic configuration of a battery device according to a fourth embodiment.

FIG. 16 is a cross-sectional view taken along line XVI-XVI in FIG. 11.

FIG. 17 is a cross-sectional view taken along line XVII-XVII in FIG. 11.

FIG. 18 is a cross-sectional view taken along line XVIII-XVIII in FIG. 11.

FIG. 19 is a diagram showing a schematic configuration of a battery monitoring device and a flexible wiring board according to a fifth embodiment.

FIG. 20 is a diagram showing a schematic configuration of a battery monitoring device and a flexible wiring board according to a sixth embodiment.

FIG. 21 is a diagram showing a schematic configuration of a flexible wiring board according to a seventh embodiment.

### DETAILED DESCRIPTION

A battery monitoring device may be connected to each battery cell via a wiring substrate. The wiring substrate includes wiring connected to the positive terminal of each battery cell and wiring connected to the negative terminal. However, depending on the configuration, the wiring substrate may have a wide spacing between the two wirings, which may result in noise entering between them.

According to a first aspect of the present disclosure, a wiring board is connected to a positive electrode terminal and a negative electrode terminal of each of battery cells. the wiring board includes a base material and a wiring. The base material is electrically insulated. The wiring includes conductive patterns and an interlayer connection member. The conductive patterns are layered with the base material interposed between the conductive patterns. The interlayer connection member electrically connects the conductive patterns in different layers. The wiring includes pair wiring portions, each of which has a positive wiring section and a negative electrode wiring section. The positive electrode wiring section is connected to the positive electrode terminal of a respective one of the battery cells, and the negative electrode wiring section connected to the negative electrode terminal of the respective one of the battery cells. The positive electrode wiring section and the negative electrode wiring section extend in parallel.

In this manner, the wiring board includes wiring having a pattern wiring layered via the base material and vias. Therefore, compared to a single-layer substrate in which the wiring is single-layered, the wiring board can offer greater flexibility in routing the wiring. Accordingly, the wiring board can suppress an increase in the distance between the positive electrode wiring section and the negative electrode wiring section in the pair wiring section. In other words, the wiring board, by providing greater flexibility in wiring layout, facilitates the formation of a pair wiring section with the positive electrode wiring section and the negative electrode wiring section. Therefore, the wiring board can reduce noise in the pair wiring portion.

According to a second aspect of the present disclosure, a battery device includes battery cells, a wiring board, and a battery monitoring device. Each of the battery cells has a positive electrode terminal and a negative electrode terminal. The wiring board is connected to the battery cells. The battery monitoring device monitors the battery cells connected to the wiring board. The wiring board includes a base material and a wiring. The wiring includes conductive patterns and an interlayer connection member. The conductive patterns are laminated through the base material. The interlayer connection member electrically connects the conductive patterns in different layers of the base material. The wiring includes pair wiring portions, each of which has a positive wiring section and a negative electrode wiring section. The positive electrode wiring section is connected to the positive electrode terminal of a respective one of the battery cells, and the negative electrode wiring section connected to the negative electrode terminal of the respective one of the battery cells. The battery monitoring device includes a battery monitoring circuit and a circuit board. The battery monitoring circuit includes first conversion circuits and second conversion circuits. Each first conversion circuit is connected to the positive electrode terminal and the negative electrode terminal of a respective one of the battery cells, and each first conversion circuit outputs an electrical signal for measuring a complex impedance of the respective one of the battery cells by converting an analog signal to a digital signal. Each second conversion circuit is connected to the positive electrode terminal and the negative electrode terminal of a respective one of the battery cells, and each second conversion circuit outputs an electrical signal for detecting a state of the respective one of the battery cells by converting an analog signal to a digital signal. The circuit board terminal pairs correspondingly provided for the first conversion circuits, and each terminal pair connects a respective one of the first conversion circuits to a target cell being a respective one of the battery cells. The pair wiring portions are connected to the terminal pairs. The positive electrode wiring section and the negative electrode wiring section extend in parallel.

In this manner, the battery device is equipped with battery cells, a wiring board connected to the battery cells, and a battery monitoring device connected to the wiring board for monitoring the battery cells. As described above, the wiring board can reduce noise in the pair wiring portion. Therefore, the battery device can output a battery voltage for complex impedance measurement from the first conversion circuit, with reduced influence from noise.

Hereinafter, multiple embodiments of the present disclosure will be described with reference to the drawings. In each embodiment, portions corresponding to those described in preceding embodiments are denoted by the same reference numerals, and redundant explanations may be omitted. In each embodiment, when only a part of the configuration is described, other portions of the configuration can be referred to and applied from other embodiments described previously.

### Battery Device

### First Embodiment

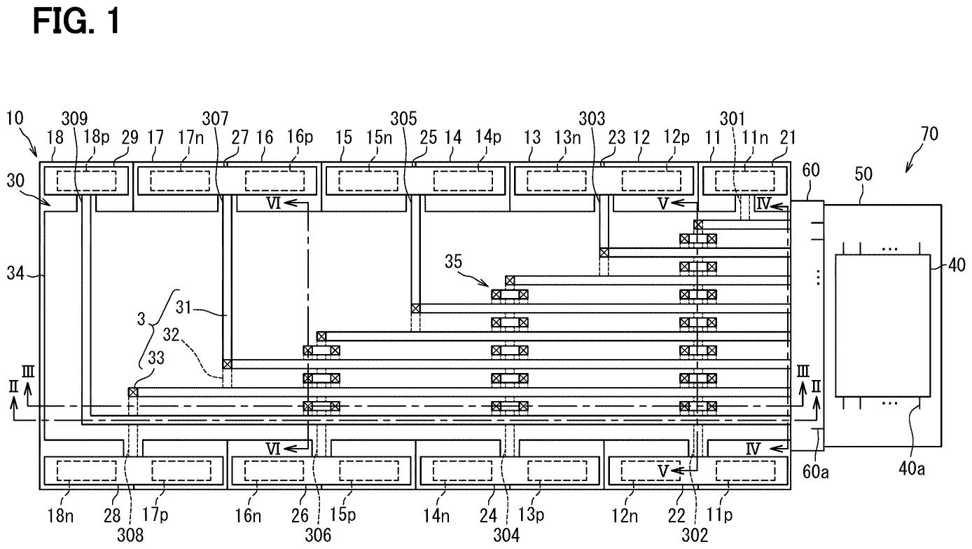

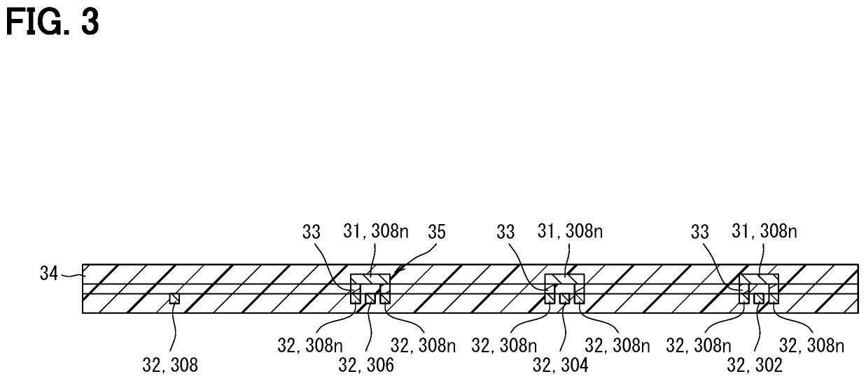

A battery device according to the present embodiment will be explained with reference to FIGS. 1 to 6. As shown in FIG. 1, the battery device mainly includes, for example, a battery pack 10, a flexible wiring board 30, and a battery monitoring device 70. The battery device is configured, for example, to be mountable on a moving object. The moving object may be, for example, a vehicle, an aircraft, a ship, a construction machine, or an agricultural machine. It should be noted that the battery device may also be referred to as a battery system. In this embodiment, as an example, the battery device including the battery pack 10 having battery cells 11 to 18 is employed. However, the battery device may only need to include the battery cells 11 to 18. In other words, the battery cells 11 to 18 do not necessarily have to be grouped into a unit such as the battery pack 10.

In the battery pack 10, the battery cells 11 to 18 are arranged side by side. In the battery pack 10, the battery cells 11 to 18 are connected in series. The flexible wiring board 30 is connected to each of the battery cells 11 to 18. Additionally, the flexible wiring board 30 is connected to the battery monitoring device 70. Then, the battery pack 10 is connected to the battery monitoring device 70 via the flexible wiring board 30. In the battery device, each of the battery cells 11 to 18 is monitored by the battery monitoring device 70. In this embodiment, as an example, one battery pack 10 and one battery monitoring device 70 associated with the battery pack 10 are employed. However, the present disclosure is not limited thereto. The battery device may include multiple battery packs 10 and multiple battery monitoring devices 70 associated with the multiple battery pack 10. The battery device may also include the multiple battery packs 10 and a battery monitoring device 70 that is commonly provided for the multiple battery packs 10. Furthermore, the battery device may include a microcontroller connected to the battery monitoring device 70. In this case, the flexible wiring board 30 may be commonly provided for the multiple battery packs 10 and the multiple battery monitoring devices 70. Additionally, the flexible wiring board 30 may be commonly provided for the multiple battery packs 10 and one battery monitoring device 70.

### Battery Pack

Each battery cell 11 to 18 may employ, for example, a lithium-ion secondary battery or a nickel-metal hydride secondary battery. In the present embodiment, as an example, the battery pack 10 equipped with eight battery cells 11 to 18 is employed. However, the battery pack 10 may only need to be equipped with multiple battery cells.

As shown in FIG. 1, the battery cells 11 to 18 include positive terminals 11p to 18p and negative terminal 11ns to 18n at both ends of the battery cells 11 to 18 in a longitudinal direction. In detail, the first battery cell 11 has a first positive terminal 11p and a first negative terminal 11n. The second battery cell 12 has a second positive terminal 12p and a second negative terminal 12n. The third battery cell 13 has a third positive terminal 13p and a third negative terminal 13n. The fourth battery cell 14 has a fourth positive terminal 14p and a fourth negative terminal 14n. The fifth battery cell 15 has a fifth positive terminal 15p and a fifth negative terminal 15n. The sixth battery cell 16 has a sixth positive terminal 16p and a sixth negative terminal 16n. The seventh battery cell 17 has a seventh positive terminal 17p and a seventh negative terminal 17n. The eighth battery cell 18 has an eighth positive terminal 18p and an eighth negative terminal 18n.

Bus bars 21 to 29 are connected to the terminals 11p to 18p and the terminals 11n to 18n. The first bus bar 21 is connected to the first negative terminal 11n. The second bus bar 22 is connected to the first positive terminal 11p and the second negative terminal 12n. The third bus bar 23 is connected to the second positive terminal 12p and the third negative terminal 13n. The fourth bus bar 24 is connected to the third positive terminal 13p and the fourth negative terminal 14n. The fifth bus bar 25 is connected to the fourth positive terminal 14p and the fifth negative terminal 15n. The sixth bus bar 26 is connected to the fifth positive terminal 15p and the sixth negative terminal 16n. The seventh bus bar 27 is connected to the sixth positive terminal 16p and the seventh negative terminal 17n. The eighth bus bar 28 is connected to the seventh positive terminal 17p and the eighth negative terminal 18n. The ninth bus bar 29 is connected to the eighth positive terminal 18p. In this manner, the multiple battery cells 11 to 18 are connected in series via the bus bars 22 to 28.

### Flexible Wiring Board

The flexible wiring board 30 will be explained with reference to FIGS. 1 to 5. In FIG. 1, for the sake of clarity, an upper layer wiring 31 is shown with solid lines and a lower layer wiring 32 is shown with dotted lines. Similarly, a via 33 is indicated by a cross mark (x).

The flexible wiring board 30 is connected to the positive terminals 11p to 18p and the negative terminals 11n to 18n of the multiple battery cells 11 to 18. The flexible wiring board 30 is a substrate for connecting the battery monitoring device 70 to the battery pack 10. The flexible wiring board 30 corresponds to a wiring substrate. In the present embodiment, a substrate having flexibility is employed as an example of a wiring substrate. However, a wiring substrate may also be employed as a rigid substrate. It should be noted that the flexible wiring board 30 only needs to be connected to the multiple battery cells 11 to 18, and does not necessarily have to correspond to the unit of the battery pack 10.

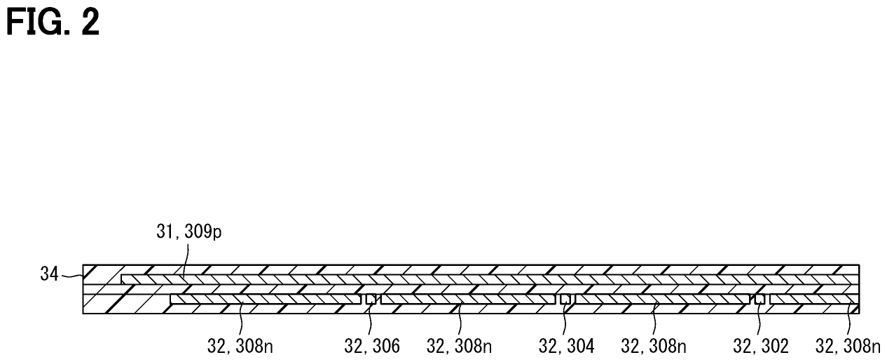

As shown in FIGS. 2 to 5, the flexible wiring board 30 includes an electrically insulating base material 34 and wiring 3 provided on the base material 34. The wiring 3 includes the upper layer wiring 31 and the lower layer wiring 32 stacked via the base material 34, as well as the via 33 that electrically connects the upper layer wiring 31 and the lower layer wiring 32 that are being different layers. It is noted that the wiring 3 is covered by the base material 34 with its end portions exposed. The end portion of the wiring 3 serve as a connection portion to the bus bars 21 to 29 and the circuit board 50.

The via 33 is mainly made of a conductive material such as copper or silver. The via 33 connects the upper layer wiring 31 and the lower layer wiring 32. The via 33 corresponds to an interlayer connection member.

The upper layer wiring 31 and the lower layer wiring 32 are mainly made of a conductive material such as aluminum or copper. The upper layer wiring 31 and the lower layer wiring 32 are patterned conductive thin films. The upper layer wiring 31 and the lower layer wiring 32 are stacked in the thickness direction of the substrate 34. The upper layer wiring 31 and the lower layer wiring 32 correspond to patterned wiring. The upper layer wiring 31 and the lower layer wiring 32 may also be referred to as wiring layer.

As shown in FIG. 1 and the like, the wiring 3 includes multiple wiring portions 301 to 309, each individually connected to the respective bus bars 21 to 29. Each of the wiring portions 301 to 309 includes the upper layer wiring 31, the via 33, and the lower layer wiring 32. One end of each of the wiring portions 301 to 309 is connected to a corresponding one of the busbars 21 to 29, and the other end is connected to the circuit board 50.

Specifically, the first wiring portion 301 is connected to the first bus bar 21. The second wiring portion 302 is connected to the second bus bar 22. The third wiring portion 303 is connected to the third bus bar 23. The fourth wiring portion 304 is connected to the fourth bus bar 24. The fifth wiring portion 305 is connected to the fifth bus bar 25. The sixth wiring portion 306 is connected to the sixth bus bar 26. The seventh wiring portion 307 is connected to the seventh bus bar 27. The eighth wiring portion 308 is connected to the eighth bus bar 28. The ninth wiring portion 309 is connected to the ninth bus bar 29.

Each of the wiring portions 301 to 309 has a section that is connected to a corresponding one of the bus bars 21 to 29, and this section is exposed from the base material 34. Similarly, each of the wiring portions 301 to 309 has a section that is connected to the circuit board, and this section is exposed from the base material 34. The section connected to the circuit board 50 is a part of a connector 60.

As described above, each of the second bus bar 22 to the eighth bus bar 28 is connected to the terminals of corresponding adjacent two of the battery cells. Therefore, each of the second wiring portion 302 to the eighth wiring portion 308 is commonly provided for two adjacent battery cells. The second wiring portion 302 to the eighth wiring portion 308 correspond to common wiring.

Therefore, each of the second wiring portion 302 to the eighth wiring portion 308 is connected to the positive terminal of one of a corresponding pair of the battery cells 11 to 18 and to the negative terminal of the other battery cell of the pair. Furthermore, each of the second wiring portions 302 to the eighth wiring portions 308 branches into a positive wiring portion and a negative wiring portion. In other words, each of the second wiring portions 302 to the eighth wiring portions 308 includes a positive wiring portion and a negative wiring portion. It is noted that the positive wiring portions 302p to 309p are also referred to as positive wiring portions 3p. On the other hand, the negative wiring portions 301n to 308n are also referred to as negative wiring portions 3n.

Specifically, the second wiring portion 302 branches into a second positive wiring portion 302p and a second negative wiring portion 302n. The second positive wiring portion 302p is a portion that functions as wiring connected to the first positive terminal 11p. The second negative wiring portion 302n is a portion that functions as wiring connected to the second negative terminal 12n.

The third wiring portion 303 branches into a third positive wiring portion 303p and a third negative wiring portion 303n. The third positive wiring portion 303p is a portion that functions as wiring connected to the second positive terminal 12p. The third negative wiring portion 303n is a portion that functions as wiring connected to the third negative terminal 13n.

The fourth wiring portion 304 branches into a fourth positive wiring portion 304p and a fourth negative wiring portion 304n. The fourth positive wiring portion 304p is a portion that functions as wiring connected to the third positive terminal 13p. The fourth negative wiring portion 304n is a portion that functions as wiring connected to the fourth negative terminal 14n.

The fifth wiring portion 305 branches into a fifth positive wiring portion 305p and a fifth negative wiring portion 305n. The fifth positive wiring portion 305p is a portion that functions as wiring connected to the fourth positive terminal 14p. The fifth negative wiring portion 305n is a portion that functions as wiring connected to the fifth negative terminal 15n.

The sixth wiring portion 306 branches into a sixth positive wiring portion 306p and a sixth negative wiring portion 306n. The sixth positive wiring portion 306p is a portion that functions as wiring connected to the fifth positive terminal 15p. The sixth negative wiring portion 306n is a portion that functions as wiring connected to the sixth negative terminal 16n.

The seventh wiring portion 307 branches into a seventh positive wiring portion 307p and a seventh negative wiring portion 307n. The seventh positive wiring portion 307p is a portion that functions as wiring connected to the sixth positive terminal 16p. The seventh negative wiring portion 307n is a portion that functions as wiring connected to the seventh negative terminal 17n.

The eighth wiring portion 308 branches into an eighth positive wiring portion 308p and an eighth negative wiring portion 308n. The eighth positive wiring portion 308p is a portion that functions as wiring connected to the seventh positive terminal 17p. The eighth negative wiring portion 308n is a portion that functions as wiring connected to the eighth negative terminal 18n.

It should be noted that the first wiring portion 301 is connected only to the first negative terminal 11n of the single first battery cell 11 among the terminals 11p to 18p and 11n to 18n. Therefore, the first wiring portion 301 is also referred to as the first negative wiring portion 301n. Similarly, the ninth wiring portion 309 is connected only to the eighth positive terminal 18p of the single eighth battery cell 18 among the terminals 11n to 18n and 11p to 18p. The ninth wiring portion 309 is also referred to as the ninth positive wiring portion 309p.

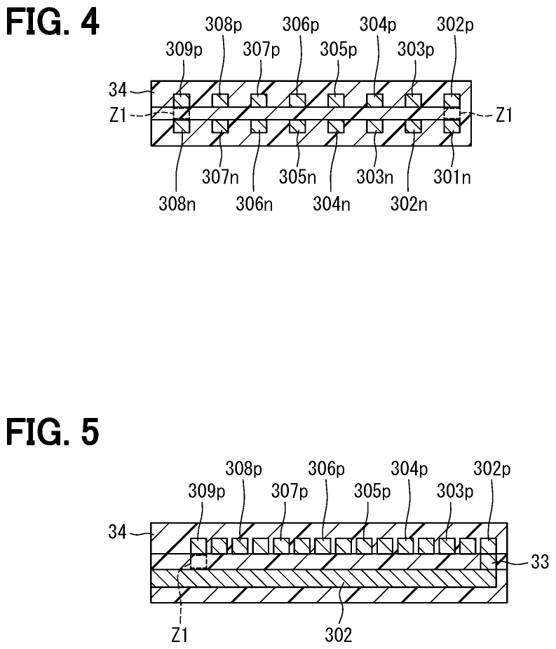

Furthermore, as shown in FIGS. 2 and 4, the positive wiring portion 3p and the negative wiring portion 3n are configured as differential pair wiring. In other words, the flexible wiring board 30 includes differential pair wirings, each of which includes a corresponding one of the positive wiring portion 302p to 309p connected to the positive terminals 11p to 18p of the respective battery cells 11 to 18, and a corresponding one of the negative wiring portion 301n to 308n connected to the negative terminals 11n to 18n of the respective battery cells 11 to 18. The flexible wiring board 30 has multiple differential pair wirings individually corresponding to each of the battery cells 11 to 18. In each differential pair wiring, the positive wiring portion and the negative wiring portion are provided to run in parallel. The differential pair wiring corresponds to a pair wiring portion. A differential pair wiring is a wiring configuration in which two conductors are arranged in parallel, and electronic signals of equal magnitude but opposite polarity are transmitted through each conductor.

Specifically, the flexible wiring board 30 includes, as differential pair wirings, a pair of the first negative wiring portion 301n and the second positive wiring portion 302p, a pair of the second negative wiring portion 302n and the third positive wiring portion 303p, a pair of the third negative wiring portion 303n and the fourth positive wiring portion 304p, and a pair of the fourth negative wiring portion 304n and the fifth positive wiring portion 305p. Additionally, the flexible wiring board 30 includes, as differential pair wirings, a pair of the fifth negative wiring portion 305n and the sixth positive wiring portion 306p, a pair of the sixth negative wiring portion 306n and the seventh positive wiring portion 307p, a pair of the seventh negative wiring portion 307n and the eighth positive wiring portion 308p, and a pair of the eighth negative wiring portion 308n and the ninth positive wiring portion 309p.

For example, the pair of the first negative wiring portion 301n and the second positive wiring portion 302p can be regarded as the differential pair wiring for the first battery cell 11. Similarly, the pair of the second negative wiring portion 302n and the third positive wiring portion 303p can be regarded as the differential pair wiring for the second battery cell 12. It can also be said that each of the second wiring portion 302 to the eighth wiring portion 308 branches into a positive wiring portion and a negative wiring portion of different differential pair wirings. Furthermore, each of the positive wiring portions 302p to 309 and each of the negative wiring portions 301n to 308n can also be regarded as parts of a corresponding one of differential pair wirings. In other words, it can be said that the differential pair wiring is formed by a part of the first negative wiring portion 301n and a part of the second positive wiring portion 302p.

Furthermore, as shown in FIG. 4, the differential pair wirings are provided on different layers via the base material 34, with the positive wiring portions 302p to 309p and the negative wiring portions 301n to 308n arranged on separate layers. In the present embodiment, as an example, a configuration is adopted in which the positive wiring portions 302p to 309p are formed in the upper layer wiring 31, and the negative wiring portions 301n to 308n are formed in the lower layer wiring 32. However, the present disclosure is not limited thereto.

Furthermore, as shown in FIG. 4, in the differential pair wirings, the positive wiring portions 302p to 309p and the negative wiring portions 301n to 308n are arranged to face each other in the thickness direction of the base material 34. In other words, the positive and negative wiring portions forming the differential pair wiring are provided so as to face each other in the thickness direction of the base material 34 and to run parallel to each other. For example, the first negative wiring portion 301n connected to the first battery cell 11 and the second positive wiring portion 302p are arranged to face each other in the thickness direction of the base material 34 and are provided so as to run parallel to each other.

However, the present disclosure is not limited thereto. The positive and negative wiring portions forming the differential pair wiring may run parallel to each other on the same layer. In other words, the positive and negative wiring portions forming the differential pair wiring may be provided in parallel on the same layer.

Each differential pair wiring is connected to each terminal pair 60a of the circuit board 50. The terminal pair 60a includes two terminals of the circuit board 50 that form a pair. Therefore, the circuit board 50 has multiple terminal pairs 60a. The multiple terminal pairs 60a are included in the connector 60. Each terminal pair 60a is individually connected to each first analog-to-digital converter (ADC) 41. The circuit board 50 and the first ADC 41 will be described hereinafter.

It is noted that, as shown in FIGS. 1, 3, and 5, there are portions on the flexible wiring board 30 where pattern wirings on the same layer intersect with each other. In the present embodiment, the lower layer wirings 32 intersect. Therefore, the flexible wiring board 30 is provided with bypass wiring sections 35 to allow the intersecting lower layer wirings 32 to pass. The bypass wiring portion 35 includes the via 33 and the upper layer wiring 31. The pattern wiring described in this present disclosure can also be referred to as a conductive pattern.

In the present embodiment, the wiring 3 is employed through which electrical signals for measuring the complex impedance of the battery cells 11 to 18, as well as electrical signals for detecting the state of the battery cells 11 to 18, flow. However, the flexible wiring board 30 may also be provided with another wiring 3 other than those described above.

### Battery Monitoring Device

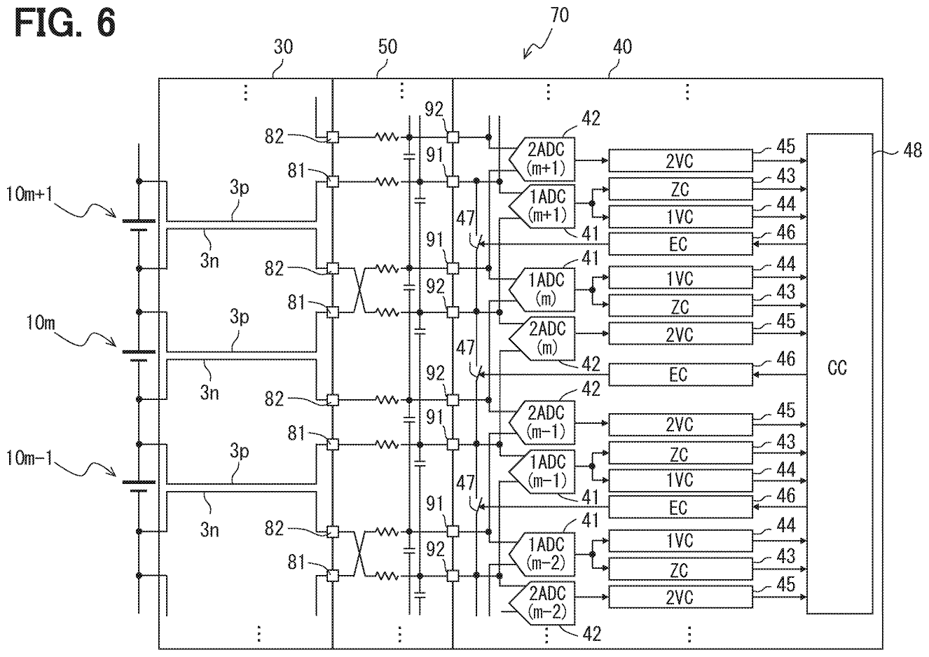

The battery monitoring device 70 will be described with reference to FIG. 1 and FIG. 6. In FIG. 6, mainly the portions corresponding to some of the battery cells 10m−1, 10m, and 10m+1 are illustrated. It should be noted that the battery cell 10m−1 and the battery cell 10m+1 are battery cells adjacent to the battery cell 10m.

As shown in FIG. 6, the battery monitoring device 70 is connected to the battery cells 11 to 18. The battery monitoring device 70 includes the battery monitoring IC 40 that monitors the battery cells 11 to 18, and the circuit board 50 that connects the battery monitoring IC 40 to the battery cells 11 to 18. More specifically, the circuit board 50 is connected to the battery cells 11 to 18 via the flexible wiring board 30. The battery monitoring IC 40 corresponds to a battery monitoring circuit. It is noted that the battery monitoring device 70 only needs to be connected to the battery cells 11 to 18, and does not necessarily have to correspond to a unit of the battery pack 10.

The flexible wiring board 30 and the circuit board 50 are connected by multiple first terminal portions 81 and multiple second terminal portions 82. The first terminal portions 81 and the second terminal portions 82 indicate the locations where the connection terminals of the flexible wiring board 30 and the connection terminals of the circuit board 50 are connected. The first terminal portions 81 and the second terminal portions 82 are included in the connector 60. A pair of the first terminal section 81 and the second terminal section 82 forms one terminal pair 60a. Therefore, it can be said that the flexible wiring board 30 and the circuit board 50 are each provided with the first terminal portions 81 and the multiple second terminal portions 82 arranged in pairs. Furthermore, the connection terminals of the circuit board 50 for the flexible wiring board 30 include multiple terminal pairs 60a and the like.

The battery monitoring IC 40 and the circuit board 50 are connected by multiple third terminal portions 91 and multiple fourth terminal portions 92. The third terminal portions 91 and the fourth terminal portions 92 indicate the locations where the connection terminals of the battery monitoring IC 40 and the connection terminals of the circuit board 50 are connected.

The connection terminals in the battery monitoring IC 40 include circuit terminal pairs 40a. The circuit terminal pair 40a includes two terminals of the battery monitoring IC 40 that are paired together. The battery monitoring IC 40 has multiple circuit terminal pairs 40a. Each of the multiple circuit terminal pairs 40a is connected to a corresponding one of the first ADCs 41. In addition, the multiple circuit terminal pairs 40a are individually connected to the multiple terminal pairs 60a. Therefore, each differential pair wiring is connected to a corresponding one of the circuit terminal pairs 40a via a corresponding one of the terminal pairs 60a.

As shown in FIG. 6, the battery monitoring IC 40 includes the first ADC 41, a second ADC 42, a complex impedance measurement circuit 43, a first voltage measurement circuit 44, a second voltage measurement circuit 45, an equalization circuit 46, an equalization switch 47, and a control circuit 48. In the drawings, the complex impedance measurement circuit 43 is denoted as ZC, the first voltage measurement circuit 44 as 1VC, the second voltage measurement circuit 45 as 2VC, the equalization circuit 46 as EC, and the control circuit 48 as CC. ADC is an abbreviation for Analog to Digital Converter. The first ADC 41 corresponds to the first conversion circuit. The second ADC 42 corresponds to the second conversion circuit.

The battery monitoring IC 40 has the circuit terminal pairs 40a, each connected to a respective first ADC 41 and to a corresponding target cell. Each of the circuit terminal pairs 40a is provided for a corresponding one of the first ADCs 41.

The first ADC 41, the second ADC 42, the complex impedance measurement circuit 43, the first voltage measurement circuit 44, and the second voltage measurement circuit 45 are provided corresponding to each of the battery cells 11 to 18. The equalization circuit 46 and the equalization switch 47 are provided corresponding to each of the battery cells 11 to 18. The control circuit 48 is provided in common for the battery cells 11 to 18.

As described above, the battery monitoring IC 40 is provided with two ADCs 41 and 42 for one battery cell. Therefore, the battery monitoring IC 40 includes the multiple first ADCs 41 and the multiple second ADCs 42. In FIG. 6, as an example, the ADCs 41 and 42 for the battery cell 10m−1, the ADCs 41 and 42 for the battery cell 10m, the ADCs 41 and 42 for the battery cell 10m+1, and the ADCs 41 and 42 for the battery cell 10m+2 are illustrated.

It is noted that the first ADC 41 for the battery cell 10m−1 and the first ADC 41 for battery cell 10m+1 can be regarded as conversion circuits adjacent to the first ADC 41 for the battery cell 10m. The battery monitoring IC 40 is also provided with the second ADC 42, paired with a corresponding one of the first ADCs 41, connected to the same battery cell.

The ADCs 41 and 42 convert analog signals into digital signals (hereinafter referred to as analog-to-digital (A/D) conversion). The start timing of the conversion period for the ADCs 41 and 42 is instructed by the control circuit 48. The ADCs 41 and 42 convert analog signals into digital signals for a predetermined period starting from the instructed timing. Hereinafter, the first ADC 41 and the second ADC 42 corresponding to the same battery cell will be described as a set.

The input terminal of the first ADC 41 is connected to the third terminal portion 91 and the fourth terminal portion 92. The third terminal portion 91 is connected to the first terminal portion 81. On the other hand, the fourth terminal portion 92 is connected to the second terminal portion 82. The first ADC 41 is connected to the positive and negative terminals of a single battery cell via the third terminal portion 91 and the fourth terminal portion 92.

It can be said that the first terminal portion 81 and the second terminal portion 82 connected to the first ADC 41 include the terminal pair 60a corresponding to the first ADC 41. For example, the first terminal portion 81 connected to the positive terminal of the battery cell 10m and the second terminal portion 82 connected to the negative terminal of the battery cell 10m include the terminal pair 60a corresponding to the first ADC 41 for the battery cell 10m. The first terminal portion 81 connected to the positive terminal of the battery cell 10m+1 and the second terminal portion 82 connected to the negative terminal of the battery cell 10m+1 include the terminal pair 60a corresponding to the first ADC 41 for the battery cell 10m+1.

The battery cell connected to the first ADC 41 corresponds to a target cell. As will be described hereinafter, the first ADC 41 outputs an electrical signal for measuring the complex impedance of the battery cell. Therefore, the target cell may also be referred to as a measurement target cell.

The output terminal of the first ADC 41 is connected to the complex impedance measurement circuit 43. The first ADC 41 converts the voltage across both terminals of the target cell into a digital signal and outputs the digital signal as an electrical signal for measuring the complex impedance of the target cell. The complex impedance measurement circuit 43 is a digital circuit that calculates the complex voltage at a specific frequency using the electrical signal. The complex voltage is a voltage for complex impedance measurement. The control circuit 48 measures (calculates) the complex impedance of the target cell using the complex voltage output from the complex impedance measurement circuit 43. In detail, the control circuit 48 is capable of acquiring the complex current flowing through the battery pack 10. Then, the control circuit 48 calculates the complex impedance using the complex voltage and complex current.

It is noted that, in the present embodiment, the control circuit 48 is employed as an example of a control circuit for measuring the complex impedance of the target cell. However, the present disclosure is not limited thereto. The complex impedance of the target cell may also be measured by a microcontroller. In other words, the microcontroller may measure the complex impedance of the battery cells in the multiple battery packs 10. In this case, the microcontroller is capable of acquiring the complex current flowing through the battery pack 10, and is capable of acquiring the complex voltage from each battery pack 10. Therefore, the microcontroller is included in the control circuit. The microcontroller may acquire the complex voltage and complex current via a communication interface. The battery monitoring device 70 may include a microcontroller.

Furthermore, the output terminal of the first ADC 41 is connected to the first voltage measurement circuit 44. The first ADC 41 converts the voltage across the target cell into a digital signal and outputs the digital signal as an electrical signal for detecting the state of the target cell. In other words, the electrical signal output by the first ADC 41 is used for complex impedance measurement and state detection. The first voltage measurement circuit 44 is a digital circuit that measures the battery voltage of the target cell using the electrical signal output from the first ADC 41. Moreover, it can be said that the first voltage measurement circuit 44 calculates the battery voltage for state detection. The first voltage measurement circuit 44 can employ, for example, a low-pass filter. The second voltage measurement circuit 45, which will be described hereinafter, is configured in a similar manner.

The input terminal of the second ADC 42 is connected to the third terminal portion 91 and the fourth terminal portion 92. The output terminal of the second ADC 42 is connected to the second voltage measurement circuit 45. The second ADC 42 converts the voltage across both ends of the target cell into a digital signal and outputs the digital signal as an electrical signal for detecting the state of the target cell.

The second voltage measurement circuit 45 is a digital circuit that measures the battery voltage of the target cell using the electrical signal output from the second ADC 42. In addition, it can be said that the second voltage measurement circuit 45 calculates the battery voltage for state detection. The second ADC 42 and the second voltage measurement circuit 45 are provided to monitor faults as the state of the target cell. It is noted that the state of the target cell may include the state of the path connected to the target cell.

The control circuit 48 monitors faults by comparing a measurement result of the first voltage measurement circuit 44 and a measurement result of the second voltage measurement circuit 45. For example, the control circuit 48 determines that a fault has occurred if the two measurement results differ, or if there is a deviation between the two measurement results exceeding a predetermined value. It is noted that the measurement results are the battery voltage of the target cell.

As described above, the paired ADCs 41 and 42 are connected to the third terminal portion 91 and the fourth terminal portion 92. However, the terminal portions 91 and 92 connected to the second ADC 42 are different from the terminal portions 91 and 92 connected to the input terminals of the paired first ADC 41. In other words, the second ADC 42 is connected to a terminal pair 60a that is linked to a different first ADC 41 than the paired first ADC 41.

As an example, an explanation will be given using the ADCs 41 and 42 for the battery cell 10m. The first ADC 41 is connected to the third terminal portion 91 and the fourth terminal portion 92, which are connected to the differential pair wiring for the battery cell 10m. On the other hand, the second ADC 42 is connected to the fourth terminal portion 92, which is connected to one side of the differential pair wiring for the battery cell 10m+1, and to the third terminal 91, which is connected to one side of the differential pair wiring for the battery cell 10m−1. In other words, the first ADC 41 is connected to the differential pair wiring for the target cell. On the other hand, the second ADC 42 is connected to the differential pair wiring for the two battery cells adjacent to the target cell. Thus, it can be said that the second ADC 42 is connected to the terminal pairs 60a that are connected to adjacent conversion circuits. It should be noted that the connected terminal pairs 60a may also be referred to as the corresponding terminal pairs 60a.

The ADCs 41 and 42 may have the same or different conversion frequencies for performing A/D conversion. Here, as one example, ADCs 41 and 42 having different conversion frequencies are employed. The multiple first ADCs 41 includes a first high-frequency circuit and a first low-frequency circuit having different conversion frequencies. Similarly, the multiple second ADCs 42 includes a second high-frequency circuit and a second low-frequency circuit having different conversion frequencies. It should be noted that “low frequency” and “high frequency” refer to relative conversion frequencies. The low-frequency circuit has a lower conversion frequency than the high-frequency circuit.

The first high-frequency circuit and the second low-frequency circuit correspond to the same target cell and are provided as a pair. The first low-frequency circuit and the second high-frequency circuit correspond to the same target cell and are provided as a pair. For example, the ADCs 41 and 42 corresponding to battery cell 10m+1 are arranged such that the first ADC 41 serves as the first low-frequency circuit, and the second ADC 42 serves as the second high-frequency circuit. The ADCs 41 and 42 corresponding to battery cell 10m are arranged such that the first ADC 41 serves as the first high-frequency circuit, and the second ADC 42 serves as the second low-frequency circuit. The ADCs 41 and 42 corresponding to battery cell 10m−1 are arranged such that the first ADC 41 serves as the first low-frequency circuit, and the second ADC 42 serves as the second high-frequency circuit.

The first high-frequency circuit and the second high-frequency circuit can also be regarded as main ADCs. The first low-frequency circuit and the second low-frequency circuit can also be regarded as sub ADCs. Additionally, the first voltage measurement circuit 44 connected to the first high-frequency circuit and the second voltage measurement circuit 45 connected to the second high-frequency circuit can also be regarded as main voltage measurement circuits. On the other hand, the first voltage measurement circuit 44 connected to the first low-frequency circuit and the second voltage measurement circuit 45 connected to the second low-frequency circuit can also be regarded as sub voltage measurement circuits.

Furthermore, all of the first ADCs 41 may have a higher conversion frequency than all of the second ADCs 42. In this case, each of the first ADCs 41 has the same conversion frequency. Similarly, each of the first ADCs 41 has the same conversion frequency. Furthermore, the ADC connected to the complex impedance measurement circuit 43 may be configured to perform A/D conversion with higher accuracy than the ADCs not connected to the complex impedance measurement circuit 43.

The equalization switch 47 is a switch used to equalize the capacitance variations among the multiple battery cells 11 to 18. In other words, the equalization switch 47 is a switch for conducting current to equalize the capacitances of the multiple battery cells 11 to 18. The equalization switch 47 is controlled to turn on and off by the equalization circuit 46.

The first ADC 41 includes a connection conversion circuit to which the equalization switch 47 is connected, and a non-connection conversion circuit to which the equalization switch 47 is not connected. The first ADC 41 for the battery cell 10m+1 and the first ADC 41 for the battery cell 10m−1 are associated with the connection conversion circuit. The first ADC 41 for the battery cell 10m is associated with the non-connection conversion circuit.

The circuit board 50 includes an electrically insulating board and a conductive wiring provided on the board. The circuit board 50 is a so-called printed circuit board.

The wiring of the circuit board 50 includes a portion that connects the first terminal portion 81 to the third terminal portion 91, and a portion that connects the second terminal portion 82 to the fourth terminal portion 92. The circuit board 50 is provided with, for example, a filter circuit including a resistor and a capacitor.

The circuit board 50 has the battery monitoring IC 40 mounted on the circuit board 50. The circuit board 50 has connection terminals to which the multiple circuit terminal pairs 40a are connected. These connection terminals are connected to the wiring of the circuit board 50. It is noted that these connection terminals can also be regarded as part of the wiring of the circuit board 50.

Additionally, the circuit board 50 has the terminal pairs 60a that are connected to each first ADC 41 and to the corresponding target cell associated with each first ADC 41. The terminal pairs 60a are provided individually for each first ADC 41. Therefore, the circuit board 50 is provided with the terminal pairs 60a. The multiple terminal pairs 60a are connected to the wiring of the circuit board 50. It is noted that the multiple terminal pairs 60a may also be regarded as part of the wiring of the circuit board 50.

### Effects

As described above, the flexible wiring board 30 includes the wiring 3 that includes the upper layer wiring 31, the lower layer wiring 32, and the via 33. Therefore, the flexible wiring board 30 can improve the routing flexibility of wiring 3 compared to a single layer wiring board in which the wiring 3 is formed in a single layer. Accordingly, the flexible wiring board 30 can suppress an increase in the distance between the positive wiring portion and the negative wiring portion in the differential pair wiring.

In other words, the flexible wiring board 30, by improving the routing flexibility of the wiring 3, facilitates the formation of differential pair wiring with the positive wiring portion and the negative wiring portion. Therefore, the flexible wiring board 30 can reduce noise in the differential pair wiring. More specifically, the flexible wiring board 30 can reduce inductive noise that enters between the positive wiring portion and the negative wiring portion forming the differential pair wiring. It is noted that the main source of inductive noise is the excitation current.

It can also be said that the flexible wiring board 30 can reduce the area Z1 between the positive wiring portion and the negative wiring portion that form the differential pair wiring. Therefore, the flexible wiring board 30 can reduce noise in the differential pair wiring. It is noted that the area Z1 can also be referred to as the noise-affected area.

Furthermore, in the flexible wiring board 30, the differential pair wiring is formed by the upper wiring 31 and the lower wiring 32. Therefore, the distance between the positive wiring portion and the negative wiring portion forming the differential pair wiring can be defined by the thickness of the base material 34 disposed between the positive wiring portion and the negative wiring portion. Therefore, the flexible wiring board 30 can reduce the distance between the positive wiring portion and the negative wiring portion of the differential pair wiring compared to forming the differential pair wiring on the same layer.

The battery monitoring device 70 includes the multiple first ADCs 41 that output battery voltages for complex impedance measurement of each of the battery cells 11 to 18. The terminal pair 60a connected to a corresponding one of the first ADCs 41 and the cell to be measured is provided individually for each first ADC 41. Therefore, the battery monitoring device 70 can more easily connect to the multiple battery cells 11 to 18 using the differential pair wiring. Therefore, the battery monitoring device 70 can output a battery voltage for state detection from the second ADC 42, and also output a battery voltage for complex impedance measurement with reduced noise influence from the first ADC 41.

Therefore, the battery monitoring device 70 can accurately measure the complex impedance of each battery cell 11 to 18. In other words, the battery monitoring device 70 can measure the complex impedance in a state where the influence of induction noise entering between the positive and negative wiring sections forming the differential pair wiring is reduced. It is noted that the battery monitoring device 70 can reduce the number of terminal sections between the battery monitoring IC 40 and the circuit board 50 compared to the configuration of the sixth embodiment, which will be described hereinafter.

In addition, the battery device includes the flexible wiring board 30 and the battery monitoring device 70. Therefore, the battery device can output a battery voltage for complex impedance measurement from the first ADC 41, with the influence of noise reduced. Thus, the battery device can accurately measure the complex impedance of each battery cell 11 to 18.

The preferred embodiments of the present disclosure have been described above. However, the present disclosure is not limited in any way to the above embodiments, and various modifications can be made without departing from the spirit of the present disclosure. The following describes other aspects of the present disclosure, specifically the second through seventh embodiments. The above embodiments, as well as the second through seventh embodiments, can be implemented individually or may be appropriately combined and implemented. The present disclosure is not limited to the combinations described in the embodiments, but can be implemented in various combinations.

### Second Embodiment

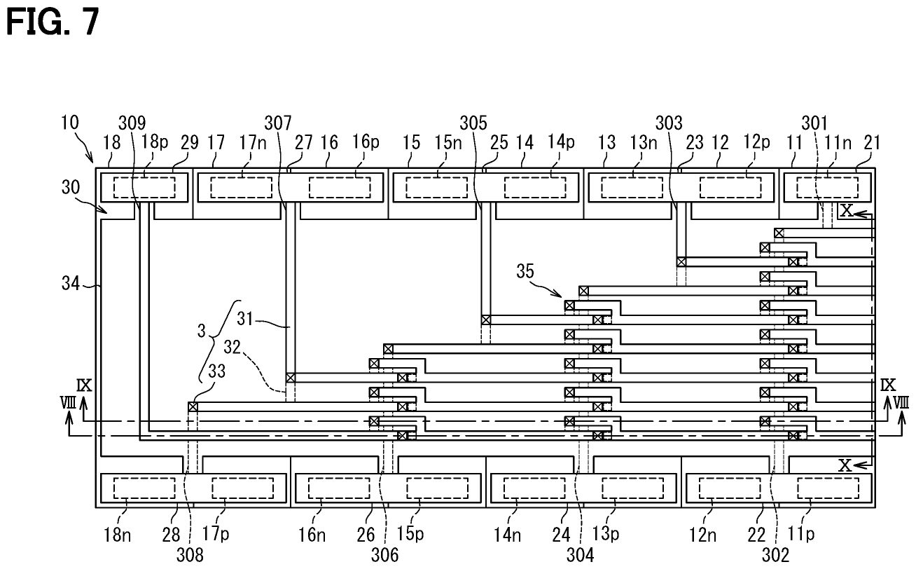

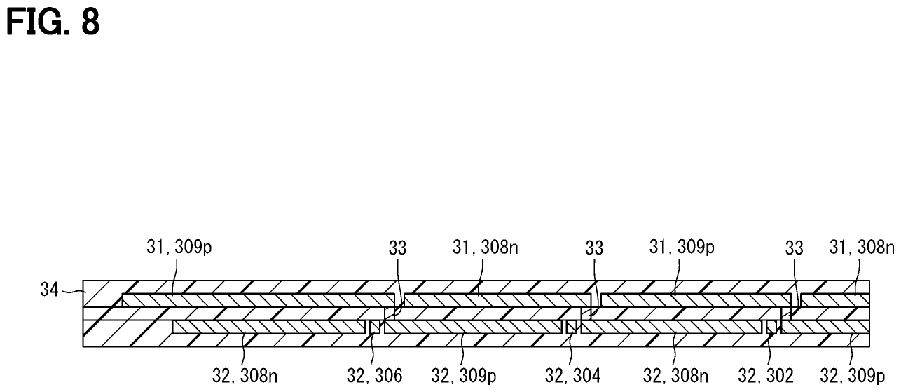

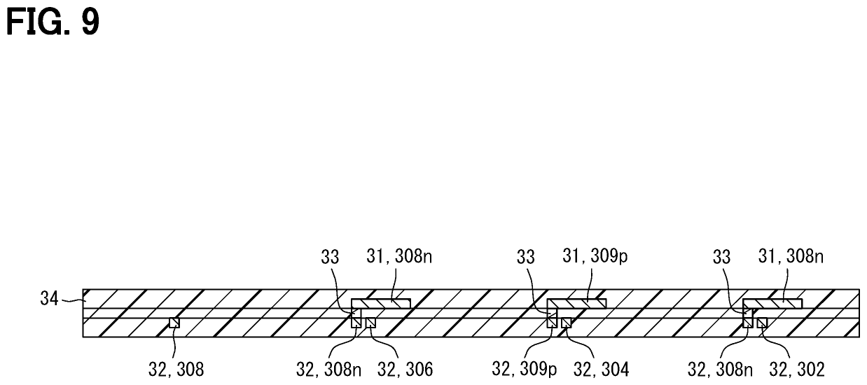

A battery device according to a second embodiment will be described with reference to FIGS. 7 to 10. In the second embodiment, the description mainly focuses on aspects that differ from the first embodiment. In the second embodiment, the flexible wiring board 30 differs from that of the first embodiment. The flexible wiring board 30 in the second embodiment has the same components as in the first embodiment, but the routing of wiring 3 is different from that in the first embodiment. FIG. 7 is a plan view corresponding to FIG. 1. In FIG. 7, the battery monitoring device 70 is omitted.

As shown in FIGS. 7, 8, and 9, the vertical relationship in the stacking direction between the positive electrode wiring portion and the negative electrode wiring portion of the differential pair wiring is partially reversed. For example, the eighth negative electrode wiring portion 308n includes the upper layer wiring 31 and the lower layer wiring 32. Similarly, the ninth positive electrode wiring section 309p includes the upper layer wiring 31 and the lower layer wiring 32.

The wiring portions 308n and 309p are partially interchanged between the upper layer wiring 31 and the lower layer wiring 32 via the vias 33 and the bypass wiring section 35. In the eighth negative electrode wiring portion 308n, the vertical relationship alternates in the order of the lower layer wiring 32, upper layer wiring 31, the lower layer wiring 32, and the upper layer wiring 31 from the side of the eighth battery cell 18. In the ninth positive electrode wiring portion 309p, the vertical relationship alternates in the order of the upper wiring 31, the lower wiring 32, the upper wiring 31, and the lower wiring 32 from the side of the eighth battery cell 18.

It is also preferable that the differential pair wiring alternates its vertical positioning at intervals crossing every even-numbered battery cell from the end. It is also preferable that the differential pair wiring alternates its vertical positioning every two battery cells.

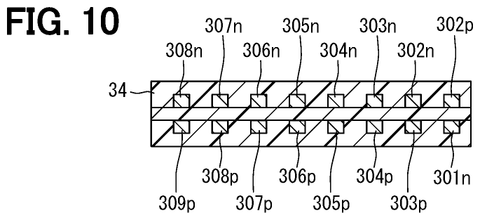

As shown in FIG. 10, an example is adopted in which, at the end on the circuit board 50 side, the differential pair wiring is configured such that the positive electrode wiring portions 303p to 309p are formed in the lower wiring layer 32, while the negative electrode wiring portions 302n to 308n are formed in the upper wiring layer 31. Furthermore, the positive electrode wiring portion 302p is formed by the upper wiring layer 31. The negative electrode wiring portion 301n is formed by the lower wiring layer 32. However, the flexible wiring board 30 may be configured such that, at the end on the circuit board 50 side, the positive electrode wiring portion 302p is formed in the lower wiring layer 32, and the negative electrode wiring portion 301n is formed in the upper wiring layer 31.

The second embodiment can achieve the same effects as the first embodiment. Furthermore, in the flexible wiring board 30, each differential pair wiring forms a twisted pair wiring. Therefore, the flexible wiring board 30 can further reduce noise in the differential pair wiring.

In other words, in the differential pair wiring, current flows through the positive and negative wiring portions due to magnetic flux passing between the two wiring portions. However, the direction of the current is reversed between adjacent sections, whose upper and lower relationships are switched. Therefore, those currents cancel each other out. Accordingly, the electrical signals flowing through the differential pair wiring are less susceptible to external influences.

Furthermore, the magnetic flux generated by the electrical signals flowing through the differential pair wiring is reversed between adjacent sections whose upper and lower relationships are switched. Therefore, those magnetic fluxes cancel each other out. Accordingly, the flexible wiring board 30 is less likely to emit noise to the outside due to the electrical signals flowing through the differential pair wiring.

The battery monitoring device 70 is connected to each of the battery cells 11 to 18 via the flexible wiring board 30. Therefore, the battery monitoring device 70 can measure the complex impedance in a state where the influence of induced noise entering between the positive electrode wiring portions 302p to 309p and the negative electrode wiring portions 301n to 308n is further reduced.

### Third Embodiment

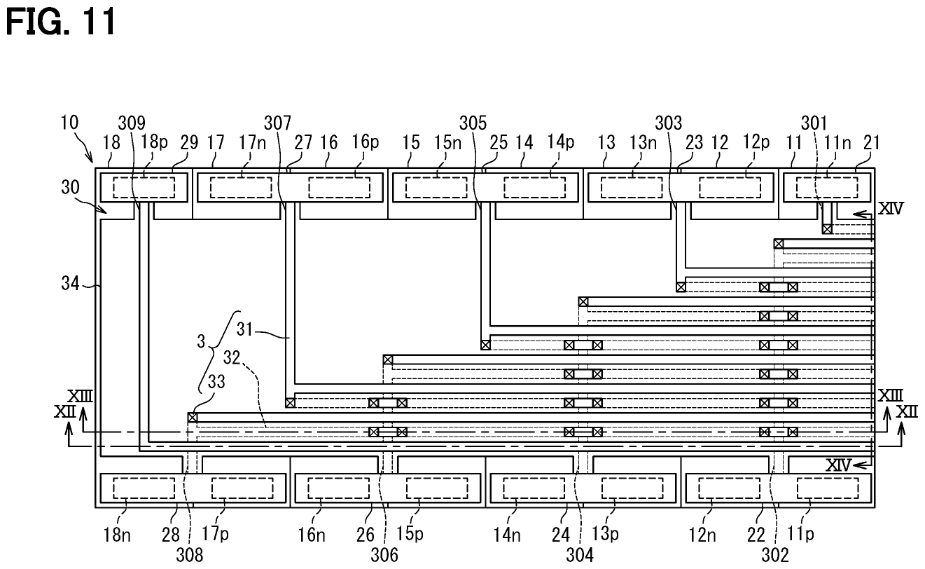

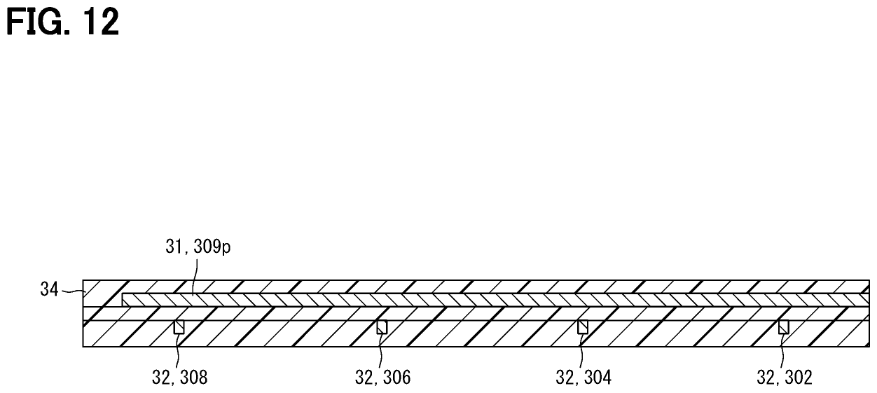

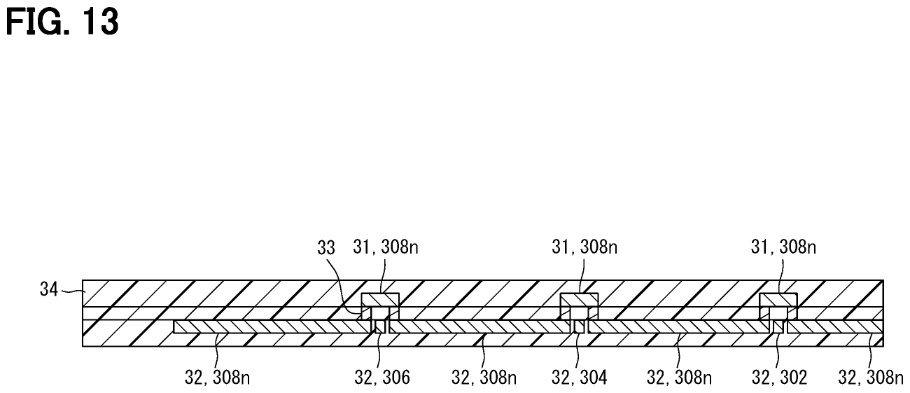

A battery device according to a third embodiment will be described with reference to FIGS. 11 to 14. In the third embodiment, the description mainly focuses on the points that differ from the first embodiment. In the third embodiment, the flexible wiring board 30 differs from that of the first embodiment. The flexible wiring board 30 in the third embodiment has the same components as in the first embodiment, but the routing of the wiring 3 differs from that in the first embodiment. FIG. 11 is a plan view corresponding to FIG. 1. In FIG. 11, the battery monitoring device 70 is omitted.

As shown in FIGS. 11, 12, and 13, in the flexible wiring board 30, the positive electrode wiring portions 302p to 309p and the negative electrode wiring portions 301n to 308n do not overlap in the stacking direction. In other words, the differential pair wiring is arranged such that the positive electrode wiring portion and the negative electrode wiring portion are offset from each other in the width direction, which is perpendicular to the thickness direction of the base material 34. For example, the positive electrode wiring portion 309p and the negative electrode wiring portion 308n are positioned offset from each other in the width direction. Therefore, the positive electrode wiring portion and the negative electrode wiring portion that form the differential pair wiring face and run parallel to each other in a diagonal positional relationship.

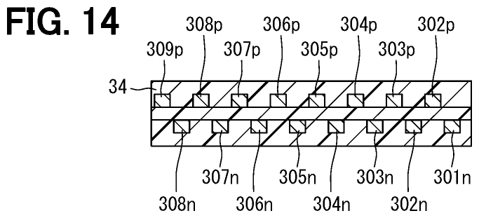

As shown in FIG. 14, at the end portion on the circuit board 50 side, the differential pair wiring is configured such that the positive wiring portions 302p to 309p are formed on the upper wiring layer 31, and the negative wiring portions 301n to 308n are formed on the lower wiring layer 32.

It is noted that the width direction coincides with the longitudinal direction of each battery cell 11 to 18. Additionally, the width direction is perpendicular to the plate thickness direction of the substrate 34, and may also be described as the direction perpendicular to the alignment direction of the battery cells 11 to 18.

The third embodiment can achieve the same effects as the first embodiment.

### Fourth Embodiment

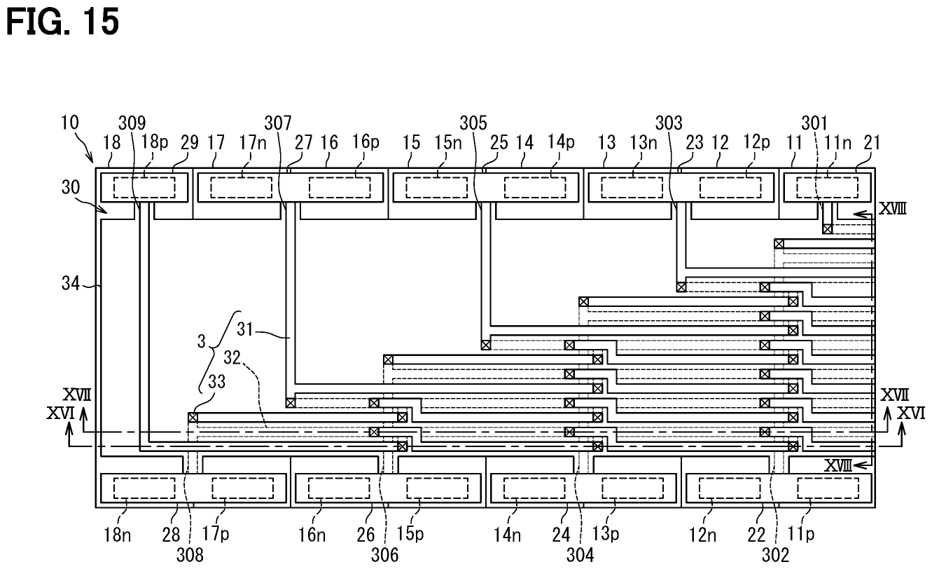

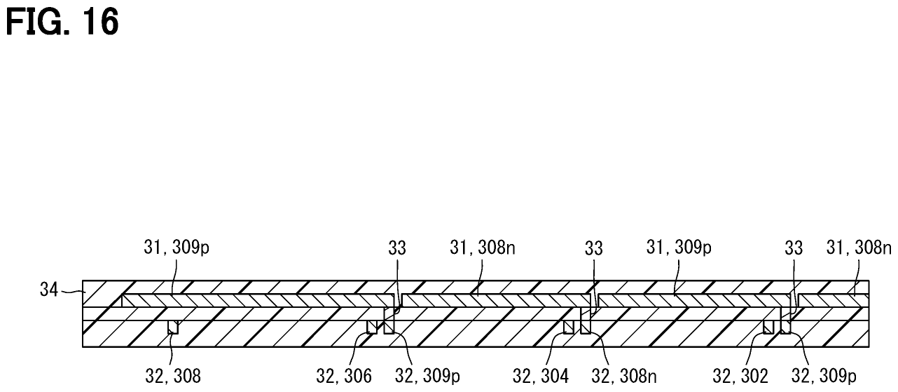

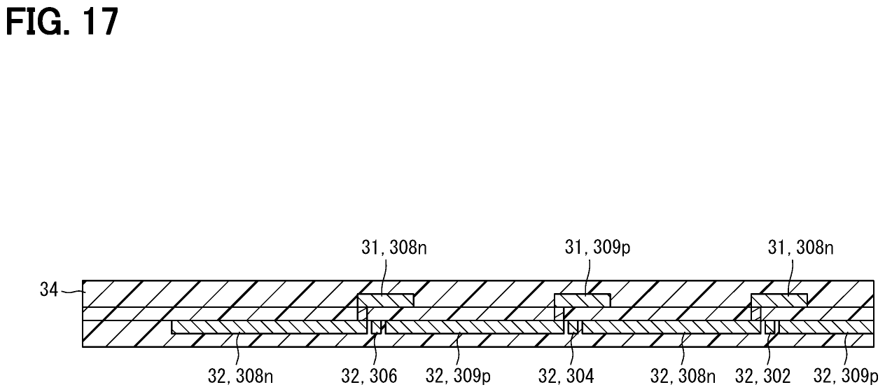

A battery device according to a fourth embodiment will be described with reference to FIGS. 15 to 18. In the fourth embodiment, the description will mainly focus on the differences from the second embodiment. In the fourth embodiment, the flexible wiring board 30 differs from that of the second embodiment. In the fourth embodiment, the flexible wiring board 30 has the same components as in the second embodiment; however, the routing of the wiring 3 differs from that in the second embodiment. FIG. 15 is a plan view corresponding to FIG. 1. In FIG. 15, the battery monitoring device 70 is omitted.

As shown in FIGS. 15, 16, and 17, the differential pair wiring is arranged such that the positive electrode wiring portion and the negative electrode wiring portion are positioned offset from each other in the width direction, which is perpendicular to the plate thickness direction of the base material 34. Furthermore, in the differential pair wiring, the vertical relationship between the positive electrode wiring portion and the negative electrode wiring portion in the stacking direction is partially reversed. In other words, the fourth embodiment is a combination of the second embodiment and the third embodiment. Therefore, the flexible wiring board 30 has each differential pair wiring configured as a twisted pair wiring.

For example, the eighth negative electrode wiring portion 308n includes the upper layer wiring 31 and the lower layer wiring 32. Similarly, the ninth positive electrode wiring section 309p includes the upper layer wiring 31 and the lower layer wiring 32. Then, in the upper layer wiring 31, a part of the ninth positive electrode wiring portion 309p and a part of the eighth negative electrode wiring portion 308n are alternately arranged. In the lower wiring layer 32, a part of the ninth positive electrode wiring portion 309p and a part of the eighth negative electrode wiring portion 308n are alternately arranged.

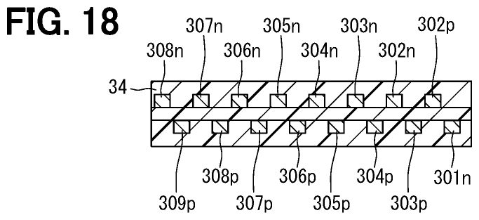

As shown in FIG. 18, the differential pair wiring is configured at the end on the circuit board 50 side in the same manner as in the second embodiment. However, the flexible wiring board 30 may be configured such that, at the end on the circuit board 50 side, the positive electrode wiring portion 302p is formed in the lower wiring layer 32, and the negative electrode wiring portion 301n is formed in the upper wiring layer 31.

The fourth embodiment can achieve the same effects as the second and third embodiments.

### Fifth Embodiment

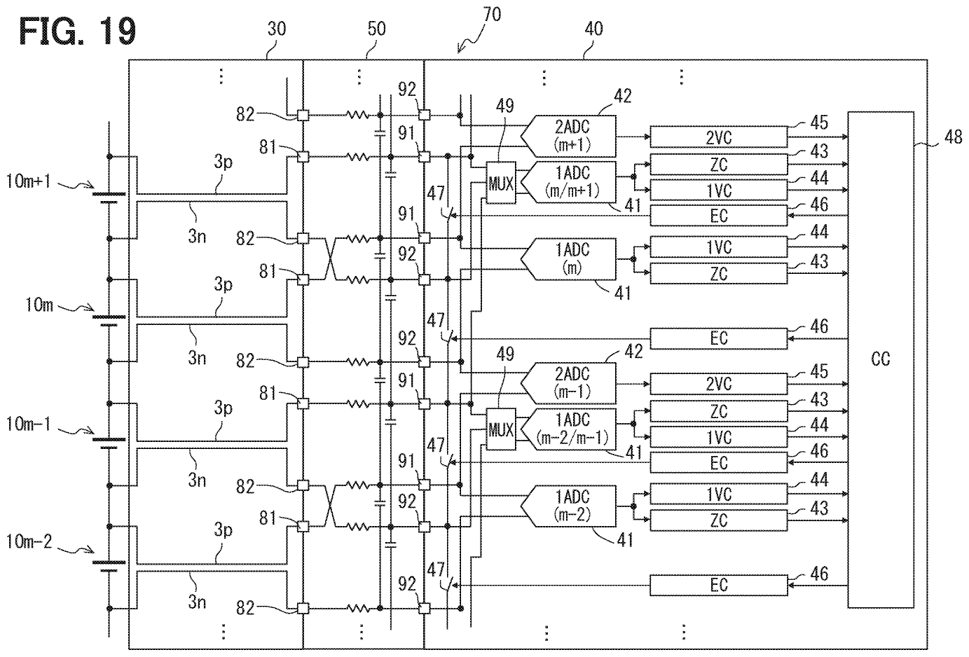

A battery device according to a fifth embodiment will be described with reference to FIG. 19. In the fifth embodiment, the explanation will mainly focus on the points that differ from the first embodiment. In the fifth embodiment, the battery monitoring IC 40 differs from that of the first embodiment. FIG. 19 is a circuit diagram corresponding to FIG. 6.

The battery monitoring IC 40 is configured such that a common first ADC 41 is provided for adjacent conversion circuits. In other words, a single first ADC 41 is provided for two adjacent battery cells. As in the first embodiment, the complex impedance measurement circuit 43 and the first voltage measurement circuit 44 are connected to the first ADC 41. On the other hand, the second voltage measurement circuit 45 is connected to the second ADC 42.

For example, a single first ADC 41 corresponds to the battery cell 10m and the battery cell 10m+1. The target cells for this first ADC 41 are the battery cell 10m and the battery cell 10m+1. In addition, another first ADC 41 corresponds to the battery cell 10m−1 and the battery cell 10m−2. The target cells for this first ADC 41 are the battery cell 10m−1 and the battery cell 10m−2.

Therefore, the battery cell 10m+1 and the battery cell 10m−1 are connected to both the second ADC 42 and the first ADC 41. When monitoring for a fault in the battery cell 10m+1 or the battery cell 10m−1, the control circuit 48 compares the measurement results from the first voltage measurement circuit 44 and the second voltage measurement circuit 45.

On the other hand, two first ADCs 41 are connected to the battery cell 10m and the battery cell 10m−2. When monitoring for faults in the battery cell 10m or the battery cell 10m−2, the control circuit 48 compares the measurement results from one first voltage measurement circuit 44 with those from the other first voltage measurement circuit 44.

It is noted that, in this embodiment as well, the ADCs 41 and 42 with different conversion frequencies may be used. For example, with respect to the battery cell 10m+1 and the battery cell 10m−1, the ADCs 41 and 42 correspond to the first ADC 41 being the first low-frequency circuit, and the second ADC 42 being the second high-frequency circuit. For example, with respect to the battery cell 10m and the battery cell 10m−2, the ADCs 41 and 42 are configured such that the common first ADC 41 serves as the first low-frequency circuit, while the other first ADC 41 serves as the first high-frequency circuit. However, the first ADC 41 and the second ADC 42 may have the same conversion frequency.

In this way, the battery monitoring IC 40 is equipped with the first ADC 41 that is commonly provided for two battery cells. Therefore, the commonly provided first ADC 41 is connected to the battery cells via a multiplexer (MUX) 49. The multiplexer 49 is controlled by the control circuit 48. Accordingly, the commonly provided first ADC 41 is selectively connected to the two battery cells.

The third embodiment can achieve the same effects as the first embodiment. Furthermore, in the third embodiment, it is possible to reduce the number of first ADCs 41 compared to the first embodiment. It should be noted that the fifth embodiment can be implemented in combination with the second through fourth embodiments or the seventh embodiment.

### Sixth Embodiment

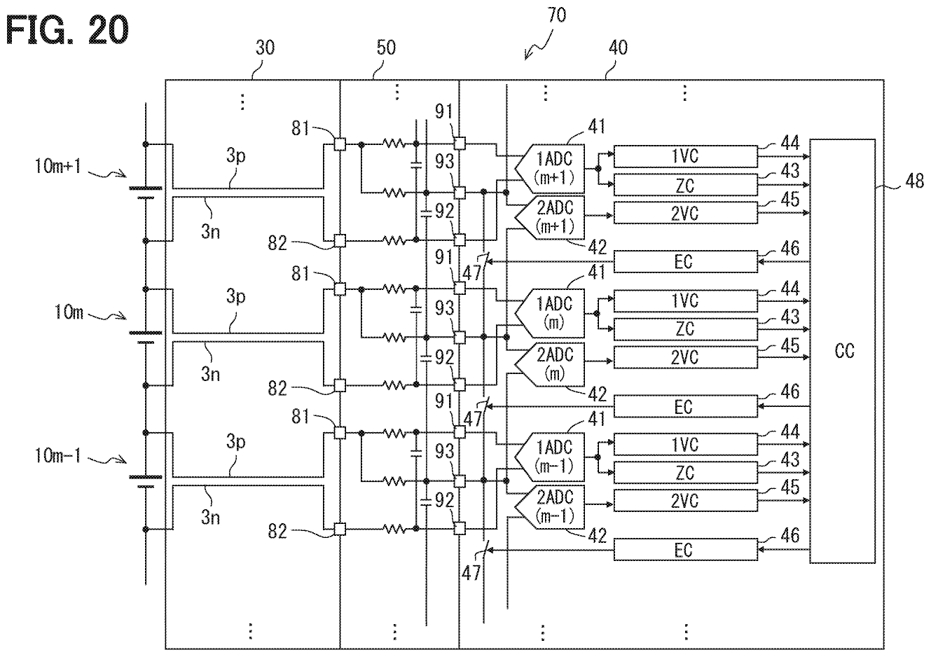

A battery device according to a sixth embodiment will be described with reference to FIG. 20. In the sixth embodiment, the differences from the first embodiment will mainly be described. In the sixth embodiment, the battery monitoring IC 40 is different from that of the first embodiment. FIG. 20 is a circuit diagram corresponding to FIG. 6.

The first ADC 41 has a higher conversion frequency than the second ADC 42. In addition, each first ADC 41 has the same conversion frequency. Similarly, each of the first ADCs 41 has the same conversion frequency.

Further, as shown in FIG. 20, the battery monitoring device 70 includes a fifth terminal portion 93 in addition to the third terminal portion 91 and the fourth terminal portion 92. The fifth terminal portion 93 is a terminal that connects the battery monitoring IC 40 and the circuit board 50. Further, the fifth terminal portion 93 is a terminal for the second ADC 42.

Although the battery monitoring device 70 has a greater number of terminal portions than in the first embodiment, the battery monitoring device 70 can output a battery voltage for complex impedance measurement from the first ADC 41, with reduced influence from noise, similarly to the first embodiment. It is noted that the sixth embodiment can be implemented in combination with the second to fourth embodiments or the seventh embodiment.

### Seventh Embodiment

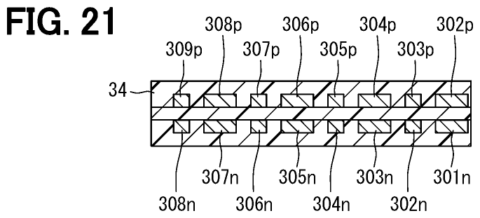

A battery device according to a seventh embodiment will be described with reference to FIG. 21. In the seventh embodiment, the description will mainly focus on the points that differ from the first embodiment. In the seventh embodiment, the flexible wiring board 30 differs from that of the first embodiment. FIG. 21 is a circuit diagram corresponding to FIG. 4.

As shown in FIG. 21, multiple differential pair wirings are arranged side by side in the width direction orthogonal to the thickness direction of the base material 34, as in the first embodiment. Furthermore, the positive and negative wiring portions of adjacent differential pair wirings have different widths. For example, the differential pair wiring connected to the even-numbered battery cells has a greater wiring width than the differential pair wiring connected to the odd-numbered battery cells. Alternatively, the differential pair wiring connected to the odd-numbered battery cells has a greater wiring width than the differential pair wiring connected to the even-numbered battery cells.

The seventh embodiment can achieve the same effects as the first embodiment. Furthermore, in the flexible wiring board 30, the wirings through which current flows for equalizing capacitance variations are arranged alternately. Therefore, it is desirable to increase the wiring width in the flexible wiring board 30 as described above, in order to increase the allowable current and reduce resistance. It us noted that the seventh embodiment can be implemented in combination with the second to fourth embodiments.

The present disclosure has been described in accordance with the embodiments, but it is understood that the present disclosure is not limited to these embodiments or structures. The present disclosure also encompasses various modifications and alterations within the scope of equivalents. In addition, although various combinations and forms are shown in the present disclosure, other combinations and forms that include only one element, more elements, or fewer elements than those disclosed are also within the scope and spirit of the present disclosure.

What is claimed is:

1. A wiring board connected to a positive electrode terminal and a negative electrode terminal of each of battery cells, the wiring board comprising:
a base material being electrically insulated; and
a wiring including
conductive patterns layered with the base material interposed between the conductive patterns; and
an interlayer connection member that electrically connects the conductive patterns in different layers, wherein
the wiring includes pair wiring portions, each of which has
a positive electrode wiring section connected to the positive electrode terminal of a respective one of the battery cells, and
a negative electrode wiring section connected to the negative electrode terminal of the respective one of the battery cells,
the positive electrode wiring section and the negative electrode wiring section extend in parallel,
the pair wiring portions are arranged side-by-side in a width direction perpendicular to a thickness direction of the base material, and
adjacent two of the pair wiring portions are different from each other in respective widths of the positive electrode wiring section and the negative electrode wiring section.

2. The wiring board according to claim 1, wherein
the positive electrode wiring section and the negative electrode wiring section are in the different layers of the conductive patterns.

3. The wiring board according to claim 2, wherein
the thickness direction of the base material corresponds to a stacking direction along which the positive electrode wiring section and the negative electrode wiring section are stacked,
in the stacking direction, the positive electrode wiring section is located above the negative electrode wiring section in at least one of the pair wiring portions, and
in the stacking direction, the negative electrode wiring section is located above the positive electrode wiring section in at least another of the pair wiring portions.

4. The wiring board according to claim 3,
wherein, when the battery cells are numbered sequentially from one end, a vertical positional relationship in the stacking direction between the positive electrode wiring section and the negative electrode wiring section is reversed at each interval, each interval corresponding to a distance spanning a respective even-numbered one of the battery cells as counted from the one end.

5. A wiring board connected to a positive electrode terminal and a negative electrode terminal of each of battery cells, the wiring board comprising:
a base material being electrically insulated; and
a wiring including
conductive patterns layered with the base material interposed between the conductive patterns; and
an interlayer connection member that electrically connects the conductive patterns in different layers, wherein
the wiring includes
pair wiring portions, each of which has
a positive electrode wiring section connected to the positive electrode terminal of a respective one of the battery cells, and
a negative electrode wiring section connected to the negative electrode terminal of the respective one of the battery cells,
the positive electrode wiring section and the negative electrode wiring section extend in parallel,
the positive electrode wiring section and the negative electrode wiring section are in the different layers of the conductive pattern
the thickness direction of the base material corresponds to a stacking direction along which the positive electrode wiring section and the negative electrode wiring section are stacked,
in the stacking direction, the positive electrode wiring section is located above the negative electrode wiring section in at least one of the pair wiring portions,
in the stacking direction, the negative electrode wiring section is located above the positive electrode wiring section in at least another of the pair wiring portions, and
when the battery cells are numbered sequentially from one end, a vertical positional relationship in the stacking direction between the positive electrode wiring section and the negative electrode wiring section is reversed at each interval, each interval corresponding to a distance spanning an even-numbered one of the battery cells as counted from the one end.

6. The wiring board according to claim 2, wherein
the positive electrode wiring section and the negative electrode wiring section face each other in the thickness direction of the base material.

7. The wiring board according to claim 2, wherein
the positive electrode wiring section and the negative electrode wiring section are in an offset positional relationship in the width direction perpendicular to the thickness direction of the base material.

8. The wiring board according to claim 1, wherein
the wiring includes a common wiring that is commonly connected to two adjacent battery cells among the battery cells,
the common wiring is connected to the positive electrode terminal of one of the two adjacent battery cells and to the negative electrode terminal of another of the two adjacent battery cells, and
the common wiring is branched into the positive electrode wiring section of one of the pair wiring portions and the negative electrode wiring section of another of the pair wiring portions.

9. A battery device comprising:
battery cells, each of which has a positive electrode terminal and a negative electrode terminal;
a wiring board connected to the battery cells; and
a battery monitoring device configured to monitor the battery cells connected to the wiring board, wherein
the wiring board includes:
a base material being electrically insulated; and
a wiring having
conductive patterns layered with the base material interposed between the conductive patterns, and
an interlayer connection member that electrically connects the conductive patterns in different layers,
the wiring includes pair wiring portions, each of which has
a positive electrode wiring section connected to the positive electrode terminal of a respective one of the battery cells, and
a negative electrode wiring section connected to the negative electrode terminal of the respective one of the battery cells,
the battery monitoring device includes:
a battery monitoring circuit having
first conversion circuits, each first conversion circuit connected to the positive electrode terminal and the negative electrode terminal of a respective one of the battery cells, each first conversion circuit configured to output an electrical signal for measuring a complex impedance of the respective one of the battery cells by converting an analog signal to a digital signal, and
second conversion circuits, each second conversion circuit connected to the positive electrode terminal and the negative electrode terminal of a respective one of the battery cells, each second conversion circuit configured to output an electrical signal for detecting a state of the respective one of the battery cells by converting an analog signal to a digital signal; and
a circuit board having terminal pairs correspondingly provided for the first conversion circuits, each terminal pair configured to connect a respective one of the first conversion circuits to a target cell being a respective one of the battery cells,
the pair wiring portions are connected to the terminal pairs,
the positive electrode wiring section and the negative electrode wiring section extend in parallel,
the pair wiring portions are arranged side-by-side in a width direction perpendicular to a thickness direction of the base material, and
adjacent two of the pair wiring portions are different from each other in respective widths of the positive electrode wiring section and the negative electrode wiring section.

10. A battery device comprising:
battery cells, each of which has a positive electrode terminal and a negative electrode terminal;
a wiring board connected to the battery cells; and
a battery monitoring device configured to monitor the battery cells connected to the wiring board, wherein
the wiring board includes:
a base material being electrically insulated; and
a wiring having
conductive patterns layered with the base material interposed between the conductive patterns, and
an interlayer connection member that electrically connects the conductive patterns in different layers,
the wiring includes pair wiring portions, each of which has
a positive electrode wiring section connected to the positive electrode terminal of a respective one of the battery cells, and
a negative electrode wiring section connected to the negative electrode terminal of the respective one of the battery cells,
the battery monitoring device includes:
a battery monitoring circuit having
first conversion circuits, each first conversion circuit connected to the positive electrode terminal and the negative electrode terminal of a respective one of the battery cells, each first conversion circuit configured to output an electrical signal for measuring a complex impedance of the respective one of the battery cells by converting an analog signal to a digital signal, and
second conversion circuits, each second conversion circuit connected to the positive electrode terminal and the negative electrode terminal of a respective one of the battery cells, each second conversion circuit configured to output an electrical signal for detecting a state of the respective one of the battery cells by converting an analog signal to a digital signal; and
a circuit board having terminal pairs correspondingly provided for the first conversion circuits, each terminal pair configured to connect a respective one of the first conversion circuits to a target cell being a respective one of the battery cells,
the pair wiring portions are connected to the terminal pairs,
the positive electrode wiring section and the negative electrode wiring section extend in parallel,
the positive electrode wiring section and the negative electrode wiring section are in the different layers of the conductive patterns,
the thickness direction of the base material corresponds to a stacking direction in which the positive electrode wiring section and the negative electrode wiring section are stacked,
in the stacking direction, the positive electrode wiring section is located above the negative electrode wiring section in at least one of the pair wiring portions,
in the stacking direction, the negative electrode wiring section is located above the positive electrode wiring section in at least another of the pair wiring portions, and
when the battery cells are numbered sequentially from one end, a vertical positional relationship in the stacking direction between the positive electrode wiring section and the negative electrode wiring section is reversed at each interval, each interval corresponding to a distance spanning an even-numbered one of the battery cells as counted from the one end.
